(19) United States
(12) Patent Application Publication
(10) Pub. No.: US 2015/0083046 A1
(43) Pub. Date: Mar. 26, 2015

(54) CARBON FIBER RING SUSCEPTOR

(71) Applicant: Applied Materials, Inc., Santa Clara, CA (US)

(72) Inventors: Joseph M. RANISH, San Jose, CA (US); Paul BRILLHART, Pleasanton, CA (US); Mehmet Tugrul SAMIR, Mountain View, CA (US); Shu-Kwan LAU, Sunnyvale, CA (US); Surajit KUMAR, Sunnyvale, CA (US)

(21) Appl. No.: 14/495,654

(22) Filed: Sep. 24, 2014

Related U.S. Application Data
(60) Provisional application No. 61/883,167, filed on Sep. 26, 2013.

(51) Int. Cl. C23C 16/458; C23C 16/48; C23C 16/46

(52) U.S. Cl. CPC C23C 16/4581; C23C 16/46; C23C 16/4585; C23C 16/481
USPC 118/724; 118/500; 118/728

(57) ABSTRACT

Embodiments described herein generally relate to an apparatus for heating substrates. In one embodiment, a susceptor comprises a ring shaped body having a central opening and a lip extending from an edge of the body that circumscribes the central opening. The susceptor comprises carbon fiber or graphene. In another embodiment, a method for forming a susceptor comprises molding carbon fiber with an organic binder into a shape of a ring susceptor and firing the organic binder. In yet another embodiment, a method for forming a susceptor comprises layering graphene sheets into a shape of a ring susceptor.

### CROSS-REFERENCE TO RELATED APPLICATIONS

This application claims benefit of United States Provisional Application Ser. No. 61/883,167, filed Sep. 26, 2013 (Attorney Docket No. APPM/020377/USL), of which is incorporated by reference in its entirety.

### BACKGROUND

1. Field of the Invention

Embodiments of the present disclosure generally relate to a carbon fiber susceptor, and more specifically, a carbon fiber ring susceptor.

2. Description of the Related Art

Semiconductor substrates are processed for a wide variety of applications, including the fabrication of integrated devices and microdevices. One method of processing substrates includes depositing a material on an upper surface of the substrate. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a susceptor, and thermally decomposing the process gas to deposit a material from the gas onto the substrate surface.

The most common epitaxial (Epi) film deposition reactors used in modern silicon technology provide similar process conditions. However, the reactor design is essential for film quality as epitaxial growth relies on the precision of gas flow to enhance epitaxial deposition uniformity. Prior susceptor designs restrict process uniformity by causing uneven thermal transfer to the substrate, which negatively influences deposition uniformity over the substrate.

Substrate heating during Epi film deposition processes is performed at high temperatures of up to 1300 degrees Celsius. Traditional susceptors are usually made from silicon carbide (SiC) or sintered graphite coated with silicon carbide, and have a high thermal mass. In instances where the susceptor is a ring susceptor, the high thermal mass of the susceptor results in inefficient and uneven thermal transfer to the backside and edge of the substrate, where there is maximum substrate to susceptor contact. The slower transfer of heat from the susceptor to the substrate, in turn, induces non-uniformity in film material properties across the substrate, and particularly at the edge of the substrate.

Thus, there is a need for an improved susceptor.

### SUMMARY

Embodiments described herein generally relate to an apparatus for heating substrates. In one embodiment, a susceptor comprises a ring shaped body having a central opening and a lip extending from an edge of the body that circumscribes the central opening. The susceptor comprises carbon fiber or graphene which have lower thermal mass than traditional susceptors.

In another embodiment, a method for forming a susceptor comprises molding carbon fiber with an organic binder into a shape of a ring susceptor and firing the organic binder. In yet another embodiment, a method for forming a susceptor comprises layering graphene sheets into a shape of a ring susceptor.

### BRIEF DESCRIPTION OF THE DRAWINGS

So that the manner in which the above recited features of the present disclosure can be understood in detail, a more particular description of the invention, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a process chamber.

FIG. 2 illustrates an enlarged cross-sectional view of a susceptor.

FIG. 3 illustrates a flow diagram for processing a substrate.

FIG. 4 illustrates a cross-section view of another embodiment of a susceptor suitable for use in the process chamber of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, for purposes of explanation, numerous specific details are set forth in order to provide a thorough understanding of the present disclosure. In some instances, well-known structures and devices are shown in block diagram form, rather than in detail, in order to avoid obscuring the present disclosure. These embodiments are described in sufficient detail to enable those skilled in the art to practice the disclosure, and it is to be understood that other embodiments may be utilized and that logical, mechanical, electrical, and other changes may be made without departing from the scope of the present disclosure.

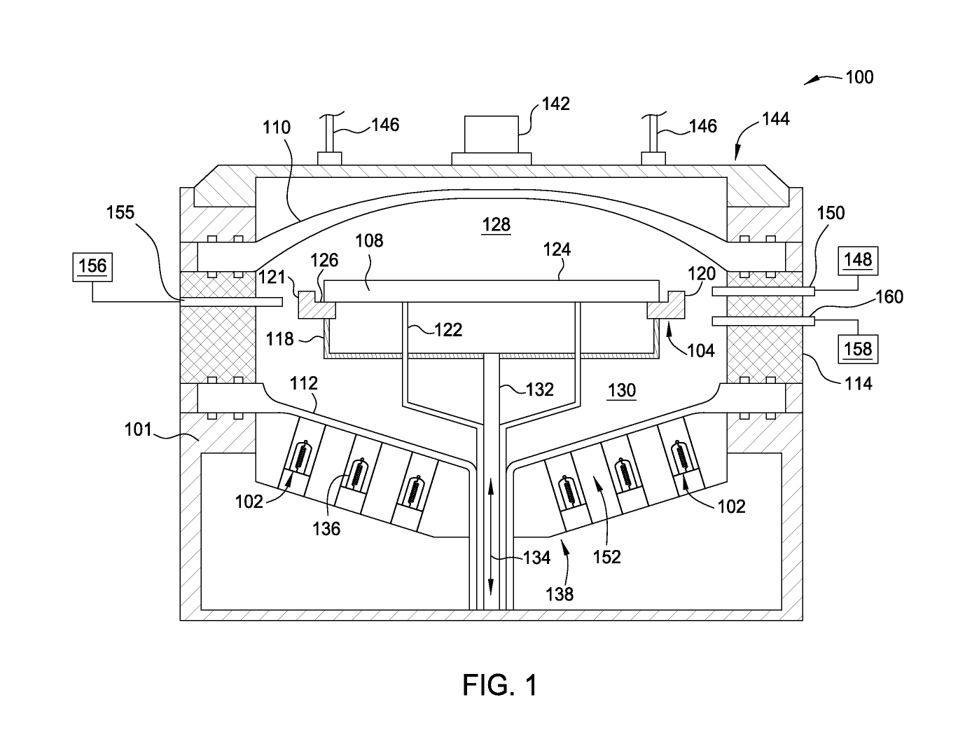

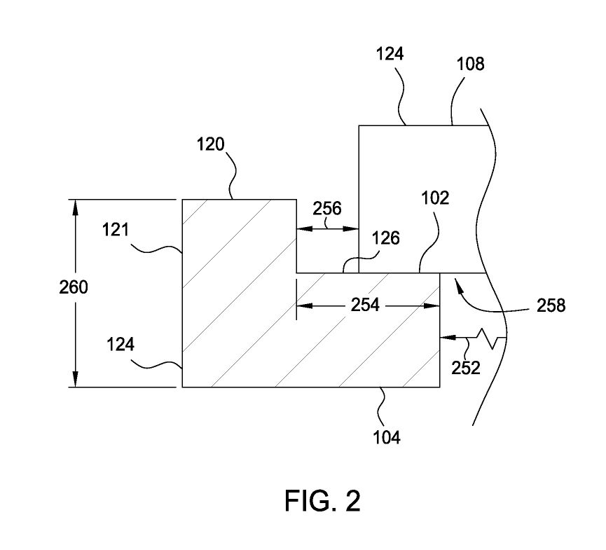

FIG. 1 illustrates a schematic view of a processing chamber 100 according to one embodiment. The processing chamber 100 may be used to process one or more substrates 108, including the deposition of a material on an upper surface of the substrate 108. The substrate 108 may include, but is not limited to 200 mm, 300 mm or larger single crystal silicon (Si), multi-crystalline silicon, polycrystalline silicon, germanium (Ge), silicon carbide (SiC), glass, gallium arsenide (GaAs), cadmium telluride (CdTe), cadmium sulfide (CdS), copper indium gallium selenide (GIGS), copper indium selenide (CuInSe₂), gallilium indium phosphide (GaInP₂), as well as heterojunction substrates, such as GaInP/GaAs/Ge or ZnSe/GaAs/Ge substrates. The processing chamber 100 may include an array of radiant heating lamps 102 for heating, among other components, a back side 104 of a susceptor 120 disposed within walls 101 of the processing chamber 100 and the substrate 108. In the embodiment shown in FIGS. 1 and 2, the susceptor 120 is has a ring shaped body with a central opening 103 and a lip 121 that extends from the edge of the susceptor 120 and circumscribes the central opening 103. The lip 121 and the front side 102 of the susceptor 120 create a pocket 126 that supports the substrate 108 from the edge of the substrate to facilitate exposure of the substrate 108 to the thermal radiation of the lamps 102. The susceptor 120 is supported by a support 118. Details of the susceptor 120 will be discussed further below in reference to FIG. 2. The susceptor 120 is located within the processing chamber 100 between an upper dome 110 and a lower dome 112. The upper dome 110, the lower dome 112 and a base ring 114 that is disposed between the upper dome 110 and lower dome 112 generally define an internal region of the processing chamber 100. In some embodiments, the array of radiant heating lamps 102 may be disposed over the upper dome 110. The substrate 108 can be brought into the processing chamber 100 and positioned onto the susceptor 120 through a loading port (not shown).

The susceptor 120 is shown in an elevated processing position, but may be moved vertically by an actuator (not shown) to a loading position below the processing position to allow lift pins 122 to pass through holes in the susceptor support 118, and raise the substrate 108 from the susceptor 120. A robot (not shown) may then enter the process chamber 100 to engage and remove the substrate 108 therefrom though the loading port. The susceptor 120 then may be actuated up to the processing position to place the substrate 108, with a device side 124 facing up, on a front side 102 of the susceptor 120.

The susceptor 120 and the susceptor support 118, while located in the processing position, divide the internal volume of the processing chamber 100 into a process gas region 128 that is above the substrate 108, and a purge gas region 130 below the susceptor 120 and the susceptor support 118. The susceptor 120 and susceptor support 118 are rotated during processing by a supporting cylindrical central shaft 132, to minimize the effect of thermal and process gas flow spatial anomalies within the processing chamber 100 and thus facilitate uniform processing of the substrate 108. The central shaft 132 moves the substrate 108 in an up and down direction 134 during loading and unloading, and in some instances, processing of the substrate 108.

In general, the central window portion of the upper dome 110 and the bottom of the lower dome 112 are formed from an optically transparent material such as quartz. One or more lamps, such as an array of the lamps 102, can be disposed adjacent to and beneath the lower dome 112 in a specified, optimal desired manner around the central shaft 132 to independently control the temperature at various regions of the substrate 108 as the process gas passes over, thereby facilitating the deposition of a material onto the upper surface of the substrate 108. While not discussed here in detail, in one embodiment, the deposited material may include silicon (Si), germanium (Ge) or dopants to create a single crystalline layer on the substrate.

The lamps 102 may be configured to include bulbs 136 and be configured to heat the substrate 108 to a temperature within a range of about 200 degrees Celsius to about 1600 degrees Celsius, for example, about 300 degrees Celsius to about 1200 degrees Celsius or about 500 to about 580 degrees Celsius. Each lamp 102 is coupled to a power distribution board (not shown) through which power is supplied to each lamp 102. The lamps 102 are positioned within a lamphead 138 which may be cooled during or after processing by, for example, a cooling fluid introduced into channels 152 located between the lamps 102. The lamphead 138 conductively and radiatively cools the lower dome 112 due in part to the close proximity of the lamphead 138 to the lower dome 112. The lamphead 138 may also cool the lamp walls and walls of the reflectors (not shown) around the lamps. Alternatively, the lower dome 112 may be cooled by a convective approach known in the industry. Depending upon the application, the lampheads 138 may or may not be in contact with the lower dome 112. As a result of backside heating of the substrate 108, the use of an optical pyrometer 142 for temperature measurements/control on the substrate 108 and the susceptor 120 may also be performed.

A reflector 144 may be optionally placed outside the upper dome 110 to reflect infrared light that is radiating off the substrate 108 back onto the substrate 108. The reflector 144 may be fabricated from a metal such as aluminum or stainless steel. The efficiency of the reflection can be improved by coating a reflector area with a highly reflective coating such as with gold. The reflector 144 can have one or more machined channels 146 connected to a cooling source (not shown). The channel 146 connects to a passage (not shown) formed on a side of the reflector 144. The passage is configured to carry a flow of a fluid such as water and may run horizontally along the side of the reflector 144 in any desired pattern covering a portion or entire surface of the reflector 144 for cooling the reflector 144.

Process gas supplied from a process gas supply source 148 is introduced into the process gas region 128 through a process gas inlet 150 formed in the sidewall of the base ring 114. The process gas inlet 150 is configured to direct the process gas in a generally radially inward direction. During the film formation process, the susceptor 120 may be located in the processing position, which is adjacent to and at about the same elevation as the process gas inlet 150, allowing the process gas to flow up and round along a flow path across the upper surface of the substrate 108 in a laminar flow fashion. The process gas exits the process gas region 128 through a gas outlet 155 located on the side of the process chamber 100 opposite the process gas inlet 150. Removal of the process gas through the gas outlet 155 may be facilitated by a vacuum pump 156 coupled thereto. As the process gas inlet 150 and the gas outlet 155 are aligned and disposed approximately at the same elevation, it is believed that such a parallel arrangement, when combined with a flatter upper dome 110 provides generally planar, uniform gas flow across the substrate 108. Further radial uniformity may be provided by the rotation of the substrate 108 through the susceptor 120.

Purge gas may be supplied from a purge gas source 158 to the purge gas region 130 through an optional purge gas inlet 160 (or through the process gas inlet 150) formed in the sidewall of the base ring 114. The purge gas inlet 160 is disposed at an elevation below the process gas inlet 150. The purge gas inlet 160 is configured to direct the purge gas in a generally radially inward direction. During the film formation process, the susceptor 120 may be located at a position such that the purge gas flows down and round along a flow path across the back side 104 of the susceptor 120 in a laminar flow fashion. Without being bound by any particular theory, the flowing of the purge gas is believed to prevent or substantially avoid the flow of the process gas from entering into the purge gas region 130, or to reduce diffusion of the process gas entering the purge gas region 130 (i.e., the region under the susceptor 120). The purge gas exits the purge gas region 130 and is exhausted out of the processing chamber 100 through the gas outlet 155, which is located on the side of the processing chamber 100 opposite the purge gas inlet 160.

FIG. 2 illustrates an enlarged cross-sectional view of the susceptor 120 according to one embodiment. While the susceptor 120 is shown in the processing chamber 100, it is contemplated that the susceptor 120 is suitable for epitaxy, rapid thermal processing, chemical vapor deposition, atomic layer deposition, or any other vacuum processes that requires uniform gas flow or temperature. Additionally, while the susceptor 120 is a ring-susceptor, it is contemplated that other susceptors (i.e., non-ring susceptors) may benefit from the foregoing disclosure.

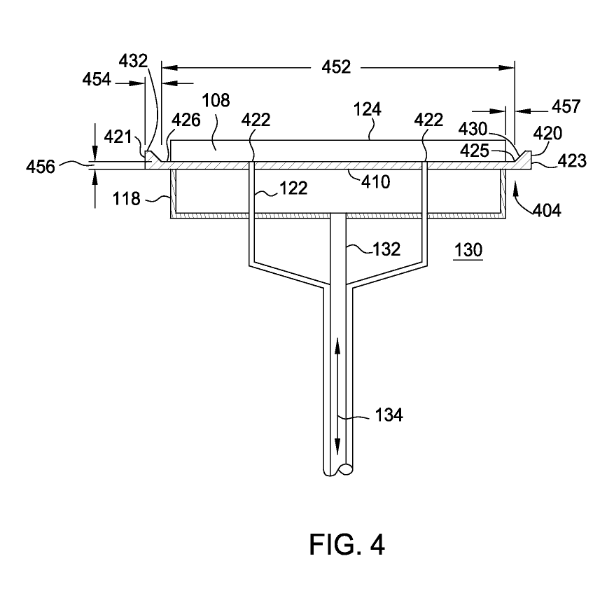

The susceptor 120 is ring shaped having an inner diameter 252 and outer diameter 124. The inner diameter 252 defines a central opening 258 of the suscepter 120 and is smaller than the diameter of the substrate 108 such that the substrate 108 may rest on the pocket 126 of the susceptor 120. The pocket 126, formed between the central opening 258 and the lip 121, may have a length 254 of about between about 1 mm and about 7 mm, such as about 4 mm. In one embodiment, the lip 121 may have a thickness 260 between about 2 mm and about 20 mm, such as about 16 mm. The thickness 260 of the lip 121 may be uniform from the pocket 126 to the outer diameter 124. Alternately, the thickness 260 of the lip 121 may increase over at least a portion of the lip 121 from the pocket 126 towards the outer the outer diameter 124. (See FIG. 4) The increase in the thickness 260 of the lip 121 near the outer diameter 124 advantageously provides strength and warpage resistance.

The susceptor 120 may be configured such that a gap 256 of about 0.5 mm is form between the substrate 108 and the lip 121. In one embodiment, the central opening 258 is about 1 mm smaller than the substrate 108 for which the susceptor 120 is configured to accept. For example, the central opening 258 of the susceptor 120 may be about 449 mm and configured accept at least a 450 mm diameter substrate. In a second example, the central opening 258 of the susceptor 120 may be about 299 mm and configured accept at least a 300 mm diameter substrate. In yet another example, the central opening 258 of the susceptor 120 may be about 199 mm and configured accept at least a 200 mm diameter substrate. The gap 256 distances the substrate 108 from the thermal mass of material associated with the lip 121 and thus promotes temperature uniformity in the substrate 108.

In one embodiment, the susceptor 120 comprises carbon fiber. The light weight and low thermal mass of carbon fiber yields a thermally agile susceptor 120 which can respond to temperature changes faster than traditional silicon carbide susceptors. In one embodiment, the susceptor 120 is thinner than traditional susceptors and has a uniform thickness less than about 5 mm, for example less than 3 mm. The thinness of the susceptor 120 advantageously minimizes the amount of physical contact between the substrate 108 and the susceptor 120.

In one embodiment, the susceptor 120 is formed by molding carbon fiber with an organic binder. The organic binder may be carbonized or graphitized during a firing process. In one embodiment, the carbon fibers in the susceptor 120 are radially aligned to provide optimal heat transfer to the substrate 108. In another embodiment, the susceptor 120 comprises graphene, an allotrope of carbon. The susceptor 120 is formed by using layers of graphene sheets such as pyrolytic carbon sheets. The graphene sheets may be about 10 microns to about 100 microns thick. In another embodiment, the susceptor 120 may be formed by layers of the pyrolytic sheets bonded with carbon fiber-carbon composites layers. In yet another embodiment, the graphene or carbon fiber susceptor 120 may be coated with silicon carbide by sintering in a furnace or oven, or any other suitable mechanism for coating.

In one example, the susceptor 120 may be formed from polyacrylonitrile (PAN)-based carbon fibers, where the carbon atoms are more randomly folded together. In another example, the carbon fiber susceptor 120 may be more graphitic, such as a heat treated mesophase pitch derived carbon fiber. In yet another example, the carbon fiber susceptor 120 may also be comprised of a composite of PAN or pitch derived carbon fiber along with other suitable materials. The graphitic carbon fiber susceptor 120 may have a higher thermal conductivity than a PAN-based carbon fiber susceptor 120 and thus the heat transfer rate may be tuned accordingly. For example, the graphitic carbon fiber susceptor 120 has quicker heat transfer across the material and heats a substrate 108 thereon more uniformly in a radial direction. Thus, the substrate 108 on the carbon fiber susceptor 120 will have a minimal thermal gradient and advantageously the carbon fiber susceptor 120 promotes uniformly in processing substrates 108 thereon.

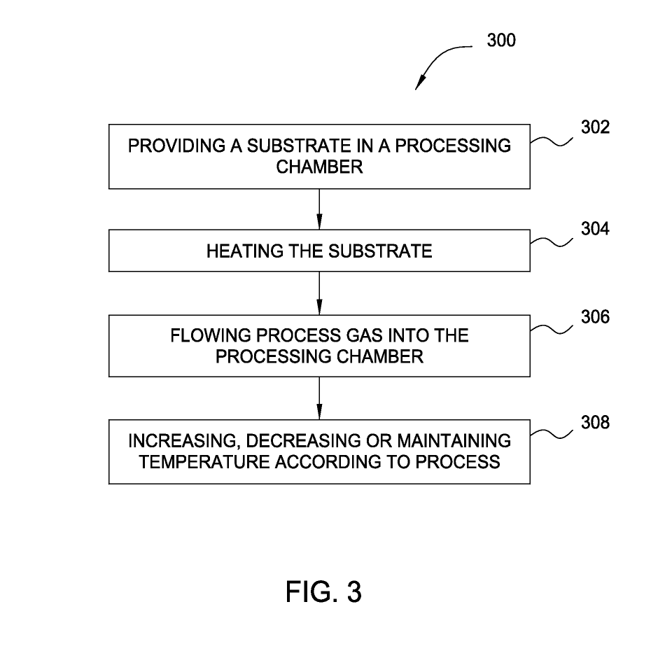

FIG. 3 illustrates a process sequence 300 which heats a substrate. In one embodiment, the sequence 300 corresponds to a process performed in the processing chamber 100. However, it is contemplated that the sequence 300 may be performed in any vacuum processing chamber that requires uniform gas flow. The process sequence 300 starts at block 302 by providing a substrate, such as the substrate 108 depicted in FIGS. 1 and 2, into a processing chamber, such as the chamber 100 depicted in FIG. 1. At block 302, the substrate 108 advantageously absorbs radiant energy from the lamps 102 at the backside of the substrate 108 through the opening 103 in the ring susceptor 120. In one embodiment, the sequence 300 is a rapid thermal processing sequence and the substrate 108 is transparent at wavelengths between about 1050 nm to about 1100 nm. The lamps 102 generate radiant energy and heat the substrate 108 to about 500 degrees Celsius or about 580 degrees Celsius, wherein the substrate 108 becomes opaque. At block 306, process gas flows into the process gas region 128. Block 306 may be performed before or after heating the substrate 108. At block 308, the temperature of the substrate 108, may be controlled (e.g., increased, decreased or maintained) depending on the process sequence 300. In one embodiment, the process sequence 300 is a rapid thermal processing sequence and the temperature is ramped up at about 300 degrees Celsius/second to reach about 1200 degrees Celsius. The power to the lamps 102 is then turned off, to allow the temperature of the substrate 108 to cool down.

FIG. 4 illustrates a cross-section view of another embodiment for a susceptor 420 suitable for use in the process chamber of FIG. 1, among others. The susceptor 420 has a body 410, a bottom surface 404, a top surface 426 and an outer perimeter 423. The body 410 of the susceptor 420 may have a plurality of lift pin holes 422 disposed therethrough from the bottom surface 404 to the top surface 426. The susceptor 420 may be circular in shape and have a lip 421 extending from the bottom surface 404 to above the top surface 426 along the outer perimeter 423 of the susceptor 420.

The lip 421 is ring shaped having an inner perimeter 425. Similar to lip 121 discussed above, the lip 421 may have a uniform thickness or have a taper 430. The taper 430 extends upward from the top surface 426 to at or near the outer perimeter 423. That is, the tapper 430 may extend to a top lip surface 432 or to the outer perimeter 423 in an embodiment without a defined top lip surface.

The inner perimeter 425 is configured to accept the substrate 108 disposed on the top surface 426 of the susceptor 420. The top surface 426 may have a length 452 corresponding to the inner perimeter 425. The length 452 may be greater than the diameter of a substrate 108, such as a 450 mm, or 300 mm or 200 mm substrate, such that a gap 457 is uniformly formed between the substrate 108 and the lip 421. The gap 457 may be about 0.1 mm to about 1 mm, such as about 0.5 mm. For example, the length 452 may be about 451 mm for a susceptor 420 configured for the 450 mm substrate.

The susceptor 420, excluding the lip 421, has a substantially uniform thickness 456 between the top surface 426 and the bottom surface 404. The thickness 456 of the susceptor 420 may be between about 1 mm and about 5 mm, such as about 3 mm. The thickness 456 may be selected to make the susceptor 420 thin yet opaque. Thus, IR thermal energy provided from below the substrate 108 placed on the susceptor 420 may uniformly and quickly change the temperature profile of the substrate 108 with little adverse impact to the pyrometers in the chamber.

In one example, the susceptor 420 may be formed from a material having a higher thermal conductivity along the length 452 than along the thickness 456. The thermal mass of the susceptor 420 may be configured by the material used to form it. The susceptor 420 may be anisotropic being stronger in the fiber direction than across the fibers. The susceptor 420 may be formed from PAN carbon fibers wherein the thermal conductivity along the fiber is high promoting a substantially uniform thermal load with little gradient from center to edge. Aligning the carbon fibers in the plane of the top surface 426 of generates a customizable thermally conductive profile for the susceptor 420. For example, the susceptor 420 may have a lower thermal conductivity from the bottom surface 404 to the top surface 426 going across the fiber grain then the thermal conductivity along the length 452 going with the fiber grains. Thus, the susceptor 420 has good in plane thermal conductivity to promote a rapid temperature profile that is uniform from center to edge of the substrate 108 place on the susceptor 420. In one embodiment the thermal conductivity in the plane of the top surface 426 is between about 10 W/(m*K) to about 1000 W/(m*K), such as about between about 60 W/(m*K) an about 600 W/(m*K), such as about 220 W/(m*K). Perpendicular to the plane of the top surface 426, the thermal conductivity of the suscepter 420 may be about 10 W/(m*K) to about 120 W/(m*K). In some embodiment, such as for composites, the perpendicular to plane thermal conductivity may be about ¼ to about 1/10 of the in plane thermal conductivity for the suscepter 420.

Advantageously, the carbon fiber or graphene susceptors 120, 420, as described above, respond quickly to the increased and decreased temperature change and has a short lag time on transfer of heat from the susceptor 120, 420 to the substrate 108. Additionally, the faster response time of the susceptor 120, 420 to temperature change makes it easier to reach a desired processing temperature. Due to the low thermal mass and thinness of the susceptor 120, 420, the susceptor 120, 420 will not draw heat from the edge of the substrate 108 and can sustain ramping of high temperatures and quick cooling down without warping or flexing. Therefore, the susceptor 120, 420 allows for more uniform heat transfer to the edge of the substrate 108 and, in turn, results in more uniform film deposition on the substrate 108.

In one example, a method for forming a susceptor may be described by molding carbon fiber with an organic binder into a shape of a ring susceptor, and carbonizing or graphitizing the organic binder in a firing process.

In another example, a method for forming a susceptor may be described by layering graphene sheets into a shape of a ring susceptor.

While the foregoing is directed to embodiments of the present disclosure, other and further embodiments may be devised without departing from the basic scope thereof, and the scope thereof is determined by the claims that follow.

1. A susceptor, comprising:
a ring shaped body having a front side and a central opening;
a lip extending from an edge of the body and circumscribing the central opening, wherein the susceptor comprises carbon fiber or graphene.

2. The susceptor of claim 1, wherein the ring shaped body has a uniform thickness of less than about 5 mm.

3. The susceptor of claim 1, wherein the ring shaped body has a uniform thickness of less than about 3 mm.

4. The susceptor of claim 1, wherein the lip and the front side of the susceptor create a pocket configured to support a substrate.

5. The susceptor of claim 1, wherein the susceptor comprises molded carbon fiber.

6. The susceptor of claim 5, wherein the carbon fiber susceptor is formed by driving off an organic binder during a firing process.

7. The susceptor of claim 1, wherein the carbon fibers in the susceptor are radially aligned.

8. The susceptor of claim 1, wherein the susceptor is coated with silicon carbide.

9. The susceptor of claim 1, wherein the graphene comprising susceptor is layered in sheets.

10. The susceptor of claim 1, wherein the central opening has a diameter of about 299 mm.

11. A susceptor, comprising:
a body having a top surface and a bottom surface and an outer perimeter;
a lip extending from the bottom side above the top side and proximate the outer perimeter, wherein the susceptor comprises carbon fiber or graphene.

12. The susceptor of claim 11, wherein the lip tapers upward from the top surface to the outer perimeter.

13. The susceptor of claim 12, wherein the tapered lip extends upward from the top surface to at or near the outer perimeter.

14. The susceptor of claim 11, wherein the susceptor is about 3 mm thick and formed from carbon fiber.

15. The susceptor of claim 14, wherein the carbon fibers are aligned in a plane of the top surface.

16. The susceptor of claim 15, wherein the thermal conductivity in the plane of the top surface is about 200 W/(m*K).

17. A deposition chamber comprising:
an upper quartz dome and a quartz lower dome;
a base ring separating the upper quartz dome and lower quartz dome; and
a susceptor having a ring shaped body with a central opening, wherein the susceptor is circumscribed within the base ring and comprises carbon fiber or graphene.

18. The deposition chamber of claim 17, wherein the ring shaped body has a uniform thickness of less than 5 mm.

19. The deposition chamber of claim 17, further comprising:
a lamp disposed between the lower quartz dome and the susceptor, wherein the lamp is oriented to provide radiant energy through the central opening in the susceptor.

20. The deposition chamber of claim 17, wherein the susceptor is coated with silicon carbide.
